(19) United States
(12) Patent Application Publication
(10) Pub. No.: US 2024/0389364 A1
(43) Pub. Date: Nov. 21, 2024

(54) COMPUTING DEVICE AND COMPUTING SYSTEM INCLUDING THE SAME

(71) Applicant: SAMSUNG ELECTRONICS CO., LTD., Suwon-si (KR)

(72) Inventors: Sangkil Lee, Suwon-si (KR); Junyoung Ko, Suwon-si (KR); Jungmin Bak, Suwon-si (KR); Changhwi Park, Suwon-si (KR)

(21) Appl. No.: 18/626,299

(22) Filed: Apr. 3, 2024

(30) Foreign Application Priority Data
May 15, 2023 (KR) 10-2023-0062504

(51) Int. Cl. H10B 80/00; G06F 12/0811; H01L 23/00; H01L 23/528; H01L 25/18

(52) U.S. Cl. CPC H10B 80/00; G06F 12/0811; H01L 24/05; H01L 24/08; H01L 25/18; H01L 23/5286; H01L 24/16; H01L 24/17; H01L 2224/05647; H01L 2224/16145; H01L 2224/16227; H01L 2224/17181; H01L 2924/1431; H01L 2924/1436; H01L 2924/1437

(57) ABSTRACT

A computing device includes a first die that includes a logic structure that includes a processing device that performs computation with respect to data, a front side line structure disposed on a front surface of the logic structure and that includes lines, and a back side power network structure disposed on a back surface of the logic structure and that provides power. The computing device further includes a second die that includes a memory device that stores the data for the computation of the processing device. The memory device includes a plurality of bank groups that respectively correspond to a plurality of channels, and the second die is bonded onto the back side power network structure by a C2C bonding method.

### CROSS-REFERENCE TO RELATED APPLICATIONS

This application claims priority under 35 U.S.C. § 119 from Korean Patent Application No. 10-2023-0062504, filed on May 15, 2023 in the Korean Intellectual Property Office, the contents of which are herein incorporated by reference in their entireties.

### TECHNICAL FIELD

Embodiments of the present disclosure described herein are directed to a computing device, and more particularly, to a computing device that includes a central processing unit and a cache memory.

### DISCUSSION

A semiconductor memory may be classified as a volatile memory that loses stored data when a power is turned off, such as a static random access memory (SRAM) or a dynamic random access memory (DRAM), or a nonvolatile memory that retains stored data when a power is turned off, such as a flash memory, a phase-change RAM (PRAM), a magnetic RAM (MRAM), a resistive RAM (RRAM), or a ferroelectric RAM (FRAM).

For a mobile-oriented semiconductor chip, performance versus power is important. As such, various system structures that provide high performance with small power consumption, such as a system architecture, a central processing unit (CPU) structure, and/or a package structure, are being suggested.

For a system architecture that utilizes a DRAM as a last level cache, because it is impossible to provide the latency and bandwidth required for a cache operation, there are limitations in improving performance. In addition, because the reduction of power consumption through a bonding structure that utilizes micro bumps is small, a system architecture that allows increased performance and reduced power consumption is desired.

### SUMMARY

Embodiments of the present disclosure provide a semiconductor device with reduced power consumption and increased operating speed.

According to an embodiment, a computing device includes a first die that includes a logic structure that includes a processing device that performs computations with respect to data, a front side line structure disposed on a front surface of the logic structure and that includes lines, and a back side power network structure disposed on a back surface of the logic structure and that provides power. The computing device further includes a second die that includes a memory device that stores the data for the computations of the processing device. The memory device includes a plurality of bank groups that respectively correspond to a plurality of channels, and the second die is bonded onto the back side power network structure by a C2C bonding method.

According to an embodiment, a computing device includes a processing device that performs computations with respect to data, an L1 cache that stores the data for the computation, an L2 cache that stores the data for the computation, where a storage capacity of the L2 cache is greater than a storage capacity of the L1 cache, and an L3 cache that stores the data for the computation, where a storage capacity of the L3 cache is greater than a storage capacity of the L2 cache. The L3 cache includes a plurality of bank groups that respectively correspond to a plurality of channels. The computing device further includes a first die that includes the processing device, the L1 cache, and the L2 cache, and a second die that includes the L3 cache. The first die and the second die are bonded by a C2C bonding method.

According to an embodiment, a computing system includes a central processing unit and a system memory. The central processing unit includes a processing device that performs computations with respect to data, an L1 cache that stores the data for the computations, an L2 cache that stores the data for the computations, where a storage capacity of the L2 cache is greater than a storage capacity of the L1 cache, and an L3 cache that stores the data for the computations, where a storage capacity of the L3 cache is greater than a storage capacity of the L2 cache. The L3 cache includes a plurality of bank groups that respectively correspond to a plurality of channels. The computing system further includes a first die that includes the processing device, the L1 cache, and the L2 cache, and a second die that includes the L3 cache. The first die and the second die are bonded by a C2C bonding method.

### BRIEF DESCRIPTION OF THE FIGURES

FIG. 1 illustrates a computing system according to an embodiment of the present disclosure.

FIG. 2 illustrates a semiconductor device that implements a computing device of FIG. 1.

FIG. 3 is a flowchart of an operation of a cache controller of FIG. 2.

FIG. 4 is a block diagram of an L3 cache of FIG. 3.

FIG. 5 illustrates a bank of FIG. 4.

FIG. 6 illustrates a first sub-array of FIG. 5.

FIG. 7 illustrates another first sub-array of FIG. 5.

FIG. 8 illustrates a semiconductor device that implements a computing device of FIG. 2.

FIG. 9 is an enlarged view of region “M” of FIG. 8, according to an embodiment.

FIG. 10 is an enlarged view of region “M” of FIG. 8, according to another embodiment.

FIG. 11 is an enlarged view of region “O” of FIG. 8, according to an embodiment.

FIG. 12 is an enlarged view of region “O” of FIG. 8, according to another embodiment.

FIG. 13 is an enlarged view of region “N” of FIG. 8.

FIG. 14 is a block diagram of a computing system that includes a computing device according to an embodiment of the present disclosure.

FIG. 15 illustrates a semiconductor device that implements a computing system of FIG. 14.

FIG. 16 is a cross-sectional view of a semiconductor device taken along line I-I′ of FIG. 15.

### DETAILED DESCRIPTION

Below, embodiments of the present disclosure will be clearly described in detail to such an extent that an ordinary one in the art can easily carry out the present disclosure.

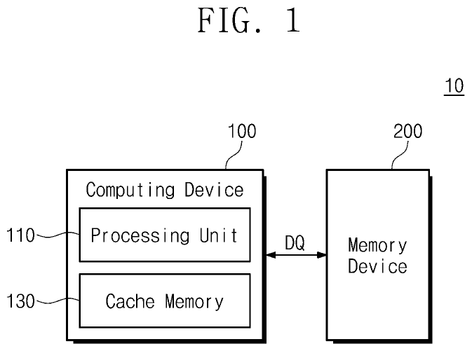

FIG. 1 illustrates a computing system according to an embodiment of the present disclosure.

Referring to FIG. 1, in an embodiment, a computing system 10 includes a computing device 100 and a semiconductor memory device 200. The computing system 10 may be a mobile device such as a desktop computer, a notebook computer, a smartphone, a personal digital assistant (PDA), a portable media player, a video game console, a television set-top box, a tablet device, an e-book reader, or a wearable device, but the computing system 10 is not necessarily limited thereto.

The computing device 100 includes a processing device 110 and a cache memory 130. The computing device 100 can process data.

The processing device 110 can process data. For example, the processing device 110 includes a central processing unit (CPU).

The cache memory 130 temporarily stores data processed by the processing device 110. For example, the cache memory 130 includes one or more of a L1 cache, L2 cache, or an L3 cache.

In the specification, an L1 cache, an L2 cache, and an L3 cache are classified depending on an operating speed and a storage capacity.

The operating speed of an L1 cache is higher than that of an L2 cache, but the storage capacity of an L1 cache is less than that of an L2 cache. For example, an L1 cache can operate at the same speed as the processing device 110. For example, L1 cache has a storage capacity of 2 KB to 64 KB.

The operating speed of an L2 cache is higher than that of an L3 cache, but the storage capacity of an L2 cache is less than that of an L3 cache. For example, an L2 cache has a storage capacity of 256 KB to 20 MB.

An L3 cache is the last level cache (LLC) of a plurality of caches. For example, an L3 cache has the greatest storage capacity of the plurality of caches. In an embodiment, a ratio of the storage capacity of an L2 cache to the storage capacity of an L3 cache may be 1:8 to 1:10.

In an embodiment of the present disclosure, an L3 cache includes a low latency wide I/O DRAM (LLW DRAM). For example, the storage capacity of an L3 cache increases, and a cache hit ratio of the L3 cache increases.

The computing device 100 can first request data from the cache memory 130 to perform data processing. When the data requested by the computing device 100 is absent from the cache memory 130, the computing device 100 accesses the semiconductor memory device 200.

For example, the computing device 100 can provide various types of control signals to the semiconductor memory device 200. For example, the computing device 100 can provide a command, an address, a control signal, and a clock signal to the semiconductor memory device 200. The computing device 100 exchanges data signals DQ with the semiconductor memory device 200 based on the command, the address, the control signal, and the clock signal.

The semiconductor memory device 200 includes at least one of various memories, such as a static random access memory (SRAM), a dynamic random access memory (DRAM), a phase-change random access memory (PRAM), a magnetic random access memory (MRAM), a ferroelectric random access memory (FeRAM), a resistive random access memory (RRAM), or a flash memory.

The semiconductor memory device 200 can be implemented with a memory module that includes two or more memory packages. For example, the memory module is implemented with a dual in-line memory module (DIMM). For another example, the semiconductor memory device 200 is implemented with an embedded memory directly mounted on a board of an electronic device.

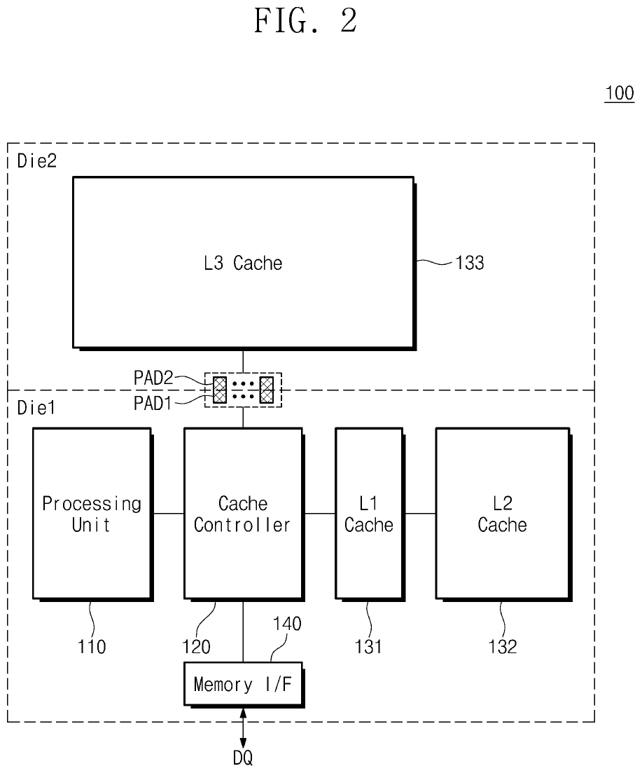

FIG. 2 illustrates a semiconductor device that implements a computing device of FIG. 1.

Referring to FIG. 2, in an embodiment, the computing device 100 includes a first die Die1 and a second die Die2. The computing device 100 is implemented by bonding the first die Die1 and the second die Die2 together. For example, the first die Die1 and the second die Die2 are bonded to each other by using a die bonding method or a wafer bonding method.

The first die Die1 includes the processing device 110, a cache controller 120, an L1 cache 131, an L2 cache 132, and a memory interface 140, and the second die Die2 includes an L3 cache 133.

The first die Die1 includes first pads PAD1. The first pads PAD1 is connected to the cache controller 120. For example, a data signal and various control signals can be exchanged with the processing device 110 through the first pads PAD1. The first pads PAD1 may be copper pads.

The second die Die2 includes second pads PAD2. The second pads PAD2 are connected to the L3 cache 133. The second pads PAD2 are connected to the first pads PAD1 of the first die Die1. For example, a data signal and various control signals can be exchanged with the L3 cache 133 through the second pads PAD2. The second pads PAD2 may be copper pads.

The first die Die1 and the second die Die2 are bonded by using a die bonding method or the wafer bonding method. In an embodiment, the first pads PAD1 of the first die Die1 and the second pads PAD2 of the second die Die2 are bonded in a cu-to-cu (C2C) bonding method. For example, the C2C bonding method is a hybrid bonding method.

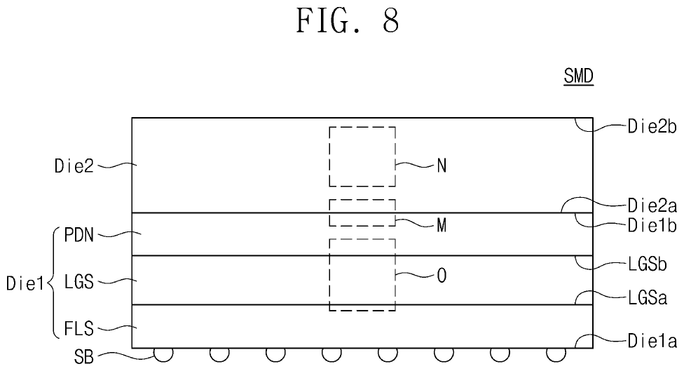

The first die Die1 and the second die Die2 will be described in detail with reference to FIGS. 8 to 13.

The processing device 110 can process data. The processing device 110 can request data for performing data processing from the cache controller 120. The processing device 110 receives the data to be processed from one of the L1 cache 131, the L2 cache 132, or the L3 cache 133.

The cache controller 120 retrieves the data requested by the processing device 110 from the L1 cache 131, the L2 cache 132, and/or the L3 cache 133.

Each of the L1 cache 131, the L2 cache 132, and the L3 cache 133 can store data to be processed by the processing device 110. When the data requested by the processing device 110 is present in at least one of the L1 cache 131, the L2 cache 132, or the L3 cache 133, the data requested by the processing device 110 is provided from caches without accessing an external semiconductor memory device, such as the semiconductor memory device 200 of FIG. 1.

When the data requested by the processing device 110 is absent from the L1 cache 131, the L2 cache 132, and the L3 cache 133, the processing device 110 accesses the external semiconductor memory device through the memory interface 140.

In an embodiment, the L1 cache 131 and the L2 cache 132 are implemented with a static random access memory (SRAM), and the L3 cache 133 is implemented with a dynamic random access memory (DRAM).

According to an embodiment of the present disclosure, the second die Die2 is bonded to the first die Die1 in the C2C bonding method. For example, the latency between the L3 cache 133 and the cache controller 120 decreases, and an operating speed increases.

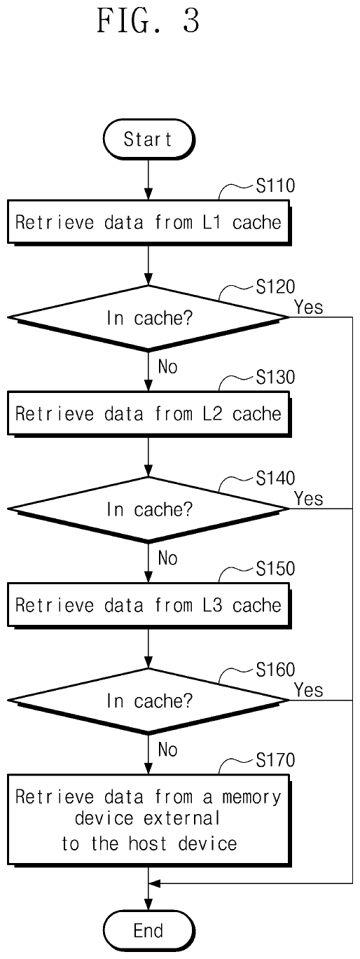

FIG. 3 is a flowchart of an operation of a cache controller of FIG. 2.

Referring to FIGS. 2 and 3, in an embodiment, in operation S110, the cache controller 120 attempts to retrieve the data requested by the processing device 110 from the L1 cache 131. When it is determined in operation S120 that the requested data is present in the L1 cache 131, the cache controller 120 transmits the requested data to the processing device 110, and the procedure terminates. When it is determined in operation S120 that the requested data is absent from the L1 cache 131, operation S130 is performed. In operation S130, the cache controller 120 attempts to retrieve the requested data from the L2 cache 132. When it is determined in operation S140 that the requested data is present in the L2 cache 132, the cache controller 120 transmits the requested data to the processing device 110, and the procedure terminates. When it is determined in operation S140 that the requested data is absent from the L2 cache 132, operation S150 is performed. In operation S150, the cache controller 120 attempts to retrieve the requested data from the L3 cache 133. When it is determined in operation S160 that the requested data is present in the L3 cache 133, the cache controller 120 transmits the requested data to the processing device 110, and the procedure terminates. When it is determined in operation S160 that the requested data is absent from the L3 cache 133, operation S170 is performed. In operation S170, the cache controller 120 retrieves the requested data from a memory device external to the computing device 100.

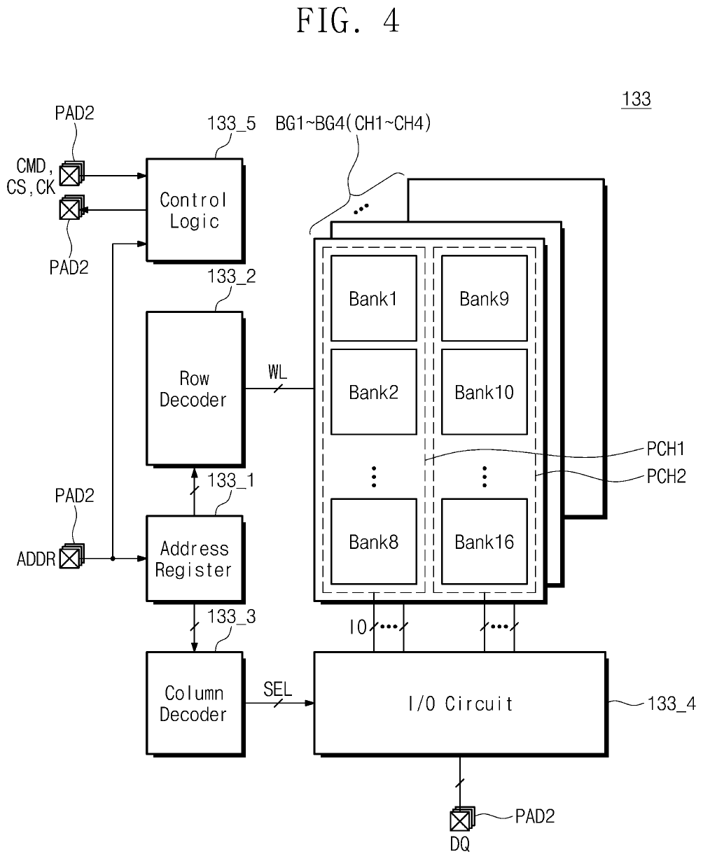

FIG. 4 is a block diagram of an L3 cache of FIG. 3.

Referring to FIG. 4, in an embodiment, the L3 cache 133 includes a dynamic random access memory (DRAM) such as a double data rate synchronous dynamic random access memory (DDR SDRAM), a low power double data rate (LPDDR) SDRAM, a graphics double data rate (GDDR) SDRAM, or a Rambus DRAM (RDRAM).

The L3 cache 133 includes first to fourth bank groups BG1 to BG4. The first to fourth bank groups BG1 to BG4 each have the same structure and operate in the same method.

The first to fourth bank groups BG1 to BG4 respectively correspond to first to fourth channels CH1 to CH4. For example, the first bank group BG1 constitutes the first channel CH1; the second bank group BG2 constitutes the second channel CH2; the third bank group BG3 constitutes the third channel CH3; and the fourth bank group BG4 constitutes the fourth channel CH4. Data can be exchanged between the processing device 110 (refer to FIG. 2) and the L3 cache 133 through the first to fourth channels CH1 to CH4.

Each of the first to fourth bank groups BG1 to BG4 includes a plurality of banks. For example, each bank group includes first to sixteenth banks. The first to sixteenth banks each have the same structure and operate in the same method. In each bank group, the first to eighth banks constitute a first pseudo channel PCH1, and the ninth to sixteenth banks constitute a second pseudo channel PCH2.

Input and output lines to which the first pseudo channel PCH1 is connected differ from input and output lines to which the second pseudo channel PCH2 is connected. For example, the number of input and output lines connected to the first pseudo channel PCH1 is 64. For example, the first pseudo channel PCH1 is a 64-bit channel. Likewise, the second pseudo channel PCH2 is a 64-bit channel. For example, each of the first to fourth channels CH1 to CH4 is a 128-bit channel. Input and output lines are independently connected to the first to fourth channels CH1 to CH4. For example, the L3 cache 133 includes the first to fourth channels CH1 to CH4 and has a 512-bit bandwidth.

The L3 cache 133 further includes an address register 133_1, a row decoder 133_2, a column decoder 133_3, an input/output circuit 133_4, and control logic 133_5.

The L3 cache 133 receives a command CMD, a control signal CS, a clock signal CK, an address ADDR, and a data signal DQ from the processing device 110 through the second pads PAD2. The second pads PAD2 are the second pads PAD2 described with reference to FIG. 2.

The address register 133_1 receives the address ADDR from the processing device 110 (refer to FIG. 2) through the second pads PAD2. The address ADDR includes a bank group address, a bank address, a row address, and a column address. The address register 133_1 provides the bank group address, the bank address, and the row address to the row decoder 133_2. The address register 133_1 provides the bank group address, the bank address, and the column address to the column decoder 133_3.

The row decoder 133_2 receives the bank group address, the bank address, and the row address from the address register 133_1. For example, the row decoder 133_2 selects one of the first to fourth bank groups BG1 to BG4 based on the bank group address. For another example, the row decoder 133_2 simultaneously selects the first to fourth bank groups BG1 to BG4. The row decoder 133_2 selects two of the first to sixteenth banks of the selected bank group, such as one of the first to eighth banks and one of the ninth to sixteenth banks, based on the bank address. The row decoder 133_2 selects a word line WL of the selected bank in the selected bank group, such as one row of memory cells, based on the row address.

The row decoder 133_2 activates the selected row by applying a voltage to the selected row of the selected bank that turns on a select element in the selected bank group. After the selected word line is activated, data bits of the memory cells in the selected row can be accessed.

The row decoder 133_2 deactivates the selected row by applying a voltage to the selected row of the selected bank that turns off the select element in the selected bank group. After the selected row is deactivated, any other row can be activated.

The column decoder 133_3 receives the bank group address, the bank address, and the column address from the address register 133_1. The column decoder 133_3 generates selection signals SEL based on the bank group address, the bank address, and the column address. The column decoder 133_3 provides the selection signals SEL to the input/output circuit 133_4.

The input/output circuit 133_4 selects at least one of a plurality of bit lines IO of the first to fourth bank groups BG1 to BG4, based on the selection signals SEL. The input/output circuit 133_4 exchanges the data signal DQ with an external device, such as the processing device 110. The input/output circuit 133_4 provides the data received from the external device to the first to fourth bank groups BG1 to BG4 or provides the data received from the first to fourth bank groups BG1 to BG4 to the external device.

The input/output circuit 133_4 outputs the data signal DQ received from the first to fourth bank groups BG1 to BG4 to the processing device 110 through the second pads PAD2.

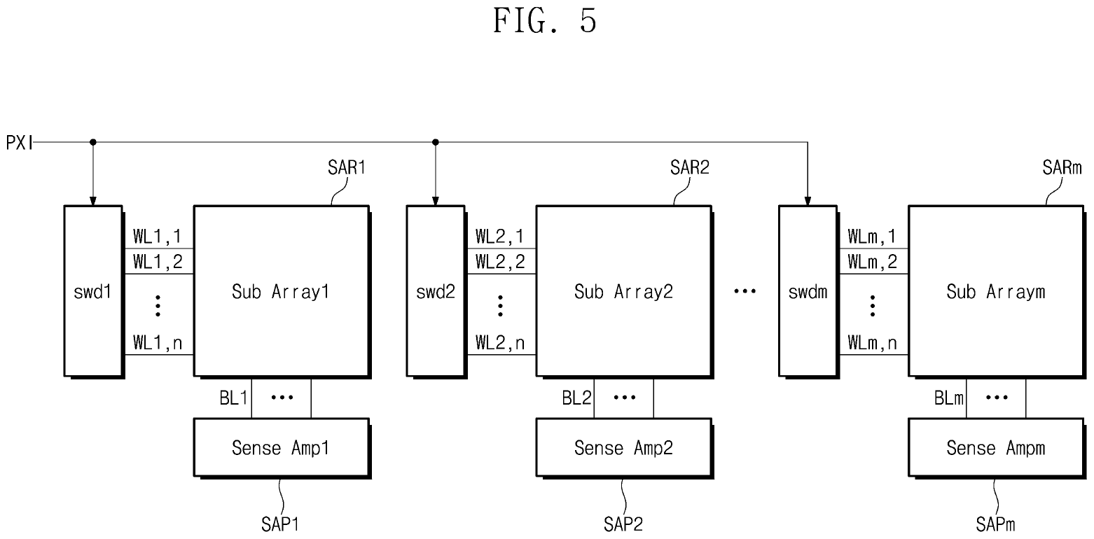

FIG. 5 illustrates a bank of FIG. 4. Below, the first bank, hereinafter referred to as a “bank”, of the first to sixteenth banks of FIG. 4 will be representatively described with reference to FIG. 5.

Referring to FIG. 5, the bank includes a plurality of sub-arrays SAR1 to SARm and a plurality of sub-word line drivers swd1 to swdm. The first to m-th sub-arrays SAR1 to SARm each have the same structure and operate in the same method.

Each of the first to m-th sub-arrays SAR1 to SARm includes a plurality of word lines and a plurality of bit lines. For example, the first sub-array SAR1 includes word lines WL1,1 to WL1,n and first bit lines BL1, the second sub-array SAR2 includes word lines WL2,1 to WL2,n and second bit lines BL2, and the m-th sub-array SARm includes word lines WLm,1 to WLm,n and m-th bit lines BLm.

In an embodiment, reference label WLx,y indicates a word line of a y-th row in an x-th sub-array. For example, the word lines WL1,1, WL2,1, and WLm,1 are included in different sub-arrays but are located in the same row, such as the first row. In an embodiment, word lines located in the same row are driven or activated by the same timing signal. For example, each of the word lines WL1,1, WL2,1, and WLm,1 may be referred to as a “first word line WLx1” that corresponds to the first row, or the word lines WL1,1, WL2,1, and WLm,1 may be understood as sharing the first word line WLx1 that corresponds to the first row.

In an embodiment, reference label BLx indicates a bit line in an x-th sub-array. A plurality of bit lines are respectively located in different columns.

The plurality of sub-arrays SAR1 to SARm and the plurality of sub-word line drivers swd1 to swdm are alternately disposed. The plurality of sub-arrays SAR1 to SARm respectively correspond to the plurality of sub-word line drivers swd1 to swdm. For example, the first sub-array SAR1 is electrically connected to the corresponding first sub-word line driver swd1. For example, the m-th array sub-array SARm is electrically connected to the corresponding m-th sub-word line driver swdm.

The first sub-word line driver swd1 is connected to the word lines WL1,1 to WL1,n of the first sub-array SAR1 and controls the word lines WL1,1 to WL1,n in response to a word line control signal PXI. The second sub-word line driver swd2 is connected to the word lines WL2,2 to WL2,n of the second sub-array SAR2 and controls the word lines WL2,2 to WL2,n in response to the word line control signal PXI. The m-th sub-word line driver swdm is connected to the word lines WLm,1 to WLm,n of the m-th sub-array SARm and controls the word lines WLm,1 to WLm,n in response to the word line control signal PXI.

For example, the plurality of sub-word line drivers swd1 to swdm include word line driving circuits. A word line driving circuit control word lines connected to the plurality of sub-word line drivers swd1 to swdm in response to the word line control signal PXI.

In an embodiment, it is assumed that the third word lines WL1,3 to WLm,3 are selected word lines. For example, in response to the word line control signal PXI, the word line driving circuits of the plurality of sub-word line drivers swd1 to swdm provide a high voltage HIGH to the selected third word lines WL1,3 to WLm,3 and provide a low voltage LOW to unselected word lines.

The plurality of sub-arrays SAR1 to SARm respectively correspond to a plurality of sense amplifiers. For example, the first sub-array SAR1 is electrically connected to a corresponding first sense amplifier SAP1. For example, the m-th sub-array SARm is electrically connected to a corresponding m-th sense amplifier SAPm.

The first sense amplifier SAP1 is connected to the first bit lines BL1 of the first sub-array SAR1. The second sense amplifier SAP2 is connected to the second bit lines BL2 of the second sub-array SAR2. The m-th sense amplifier SAPm is connected to the m-th bit lines BLm of the m-th sub-array SARm.

Each of the first to m-th sense amplifiers SAP1 to SAPm includes a plurality of sense amplifiers. Each sense amplifier is connected to a pair of bit lines.

Voltages of the paired bit lines are complementary to each other. For example, during a given time period, when one voltage level is high, the other voltage level is low. As each of the plurality of sense amplifier amplifies a voltage difference of the corresponding paired bit lines, data bits stored in the memory cells of the activated row can be sensed.

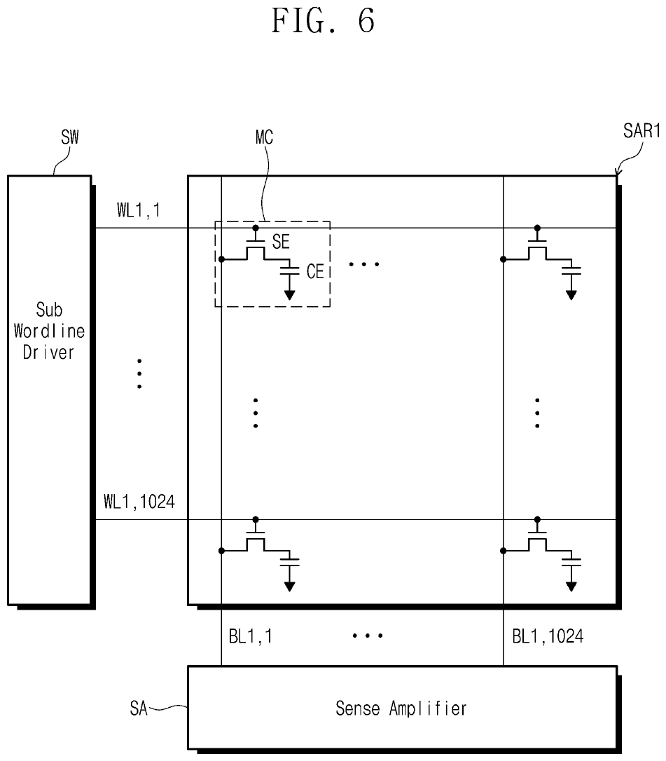

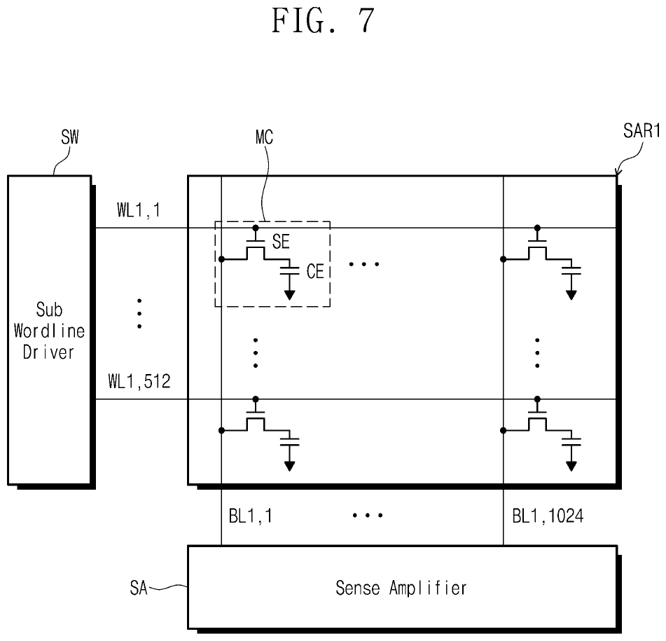

FIG. 6 illustrates a first sub-array of FIG. 5. FIG. 7 illustrates another first sub-array of FIG. 5. Below, the first sub-array SAR1 of FIG. 5 will be representatively described with reference to FIGS. 6 and 7.

Referring to FIGS. 6 and 7, in an embodiment, the first sub-array SAR1 includes a plurality of memory cells MC. Each of the memory cells MC includes a select transistor SE and a capacitive element CE. The select transistor SE operates in response to a voltage of a corresponding word line. When the corresponding word line is activated, or when a high voltage is applied to the corresponding word line, the select transistor SE is turned on and electrically connects the capacitive element CE with a corresponding bit line. When the corresponding word line is deactivated, or when a low voltage is applied to the corresponding word line, the select transistor SE is turned off and electrically disconnects the capacitive element CE from the corresponding bit line.

The capacitive element CE is connected between the select transistor SE and a common node to which a common voltage is applied. The capacitive element CE is implemented with a capacitor. The capacitive element CE stores a data bit by storing a voltage received from the corresponding bit line through the select transistor SE. For example, the common voltage is one of a power supply voltage, a ground voltage, or a voltage having a level between the power supply voltage and the ground voltage, such as a level that corresponds to half of the power supply voltage level.

When a specific word line, such as WL1,1, is activated, data bits stored in memory cells MC connected to the activated word line WL1,1 can be read. For example, a voltage change occurs in the capacitive elements CE of the memory cells MC of the activated word line WL1,1.

When a specific word line, such as WL1,1, is activated, data bits can be written to the memory cells MC connected to the activated word line WL1,1. For example, a voltage change occurs in the capacitive elements CE of the memory cells MC of the activated word line WL1,1.

The first sub-array SAR1 includes a plurality of word lines and a plurality of bit lines. In FIGS. 6 and 7, reference label BL1,y refers to a bit line of a y-th column of the first sub-array SAR1.

Returning again to FIG. 6, in an embodiment, the number of word lines connected to the first sub-array SAR1 is equal to the number of bit lines connected to the first sub-array SAR1.

For example, the number of word lines in the first sub-array SAR1 is 1024, and the number of bit lines in the first sub-array SAR1 is 1024. For example, 1024 memory cells MC are connected to one bit line, and 1024 memory cells MC are connected to one word line.

Referring to FIG. 7, in an embodiment, fewer memory cells are connected to one bit line.

For example, the number of word lines in the first sub-array SAR1 is 512, and the number of bit lines in the first sub-array SAR1 is 1024. For example, 512 memory cells MC are connected to one bit line, and 1024 memory cells MC are connected to one word line.

For example, the number of word lines connected to the first sub-array SAR1 is less than the number of bit lines connected to the first sub-array SAR1. For example, the number of word lines connected to the first sub-array SAR1 is half the number of bit lines connected to the first sub-array SAR1.

In an embodiment of the present disclosure, as the number of memory cells connected to one bit line decreases, a loading time of the memory cells decreases, and thus, the latency additionally decreases.

FIG. 8 illustrates a semiconductor device that implements a computing device of FIG. 2.

Referring to FIG. 8, in an embodiment, a semiconductor device SMD includes the first die Die1 and the second die Die2. As illustrated in FIG. 2, the first die Die1 includes the processing device 110, the cache controller 120, the L1 cache 131, and the L2 cache 132. As illustrated in FIG. 2, the second die Die2 includes the L3 cache 133.

The first die Die1 includes a logic structure LGS, a front side line structure FLS, and a back side power network structure PDN.

The logic structure LGS includes an integrated circuit that operates as the processing device 110, the cache controller 120, the L1 cache 131, and the L2 cache 132. For example, the logic structure LGS includes a substrate and electronic elements on the substrate, such as a transistor.

The logic structure LGS includes a front surface LGSa and a back surface LGSb that faces away from the front surface. The integrated circuit is disposed adjacent to the front surface LGSa of the logic structure LGS, and the substrate is disposed adjacent to the back surface LGSb of the logic structure LGS.

The front side line structure FLS is disposed on the front surface LGSa of the logic structure LGS. The front side line structure FLS includes lines that are connected to the electronic elements of the logic structure LGS.

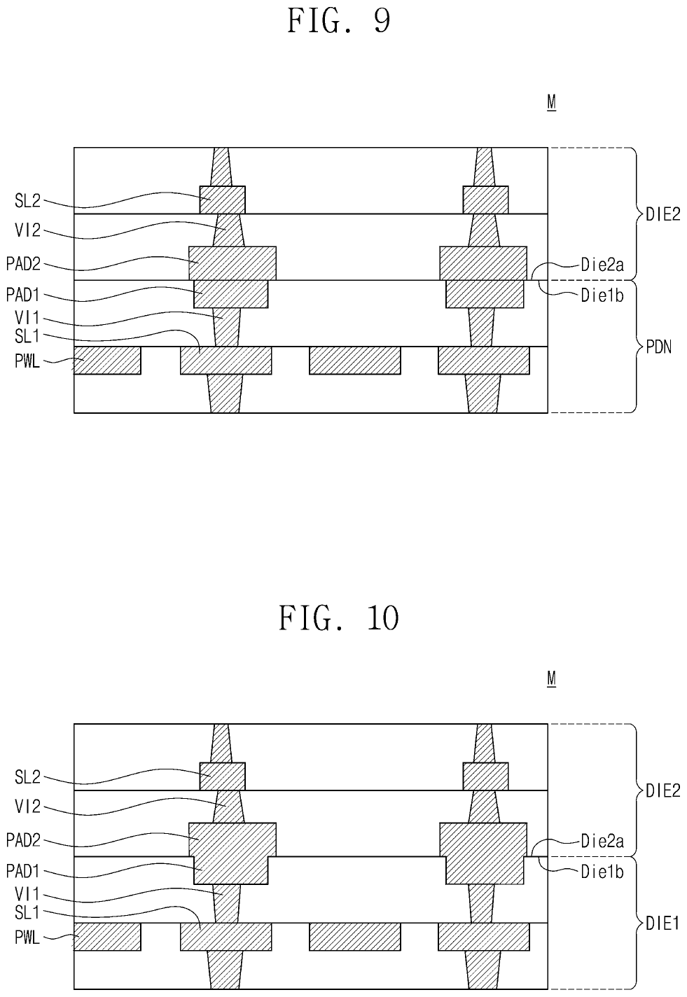

The back side power network structure PDN is disposed on the back surface LGSb of the logic structure LGS. The back side power network structure PDN provides power to the logic structure LGS. For example, the back side power network structure PDN includes power lines PWL (refer to FIG. 9) that transmit power to the integrated circuit of the logic structure LGS. In an embodiment, the back side power network structure PDN further includes signal lines for exchanging a control signal and a data signal with the logic structure LGS.

The first die Die1 includes a first die front surface Die1a and a first die back surface Die1b that faces away from the first die front surface Die1a. Solder balls SB are disposed on the first die front surface Die1a of the first die Die1. The front side line structure FLS is disposed adjacent to the first die front surface Die1a of the first die Die1. The back side power network structure PDN is disposed adjacent to the first die back surface Die1b of the first die Die1.

The second die Die2 includes a second front surface Die2a and a second back surface Die2b that faces away from the second front surface Die2a. The second front surface Die2a of the second die Die2 is bonded to the first die back surface Die1b of the first die Die1. The first die Die1 is attached onto the second front surface Die2a of the second die Die2.

In an embodiment, the back side power network structure PDN of the first die Die1 includes the first pads PAD1 (refer to FIG. 2) and first signal lines SL1 (refer to FIG. 9). The first pads PAD1 are disposed on the first die back surface Die1b. The first signal lines are electrically connected to the first pads PAD1 and the logic structure LGS.

In an embodiment, the second die Die2 includes the second pads PAD2 (refer to FIGS. 2 and 4) and second signal lines SL2 (refer to FIGS. 9 and 10). The second pads PAD2 are disposed on the second front surface Die2a. The logic structure LGS exchanges a control signal and a data signal with the second die Die2 through the first signal lines SL1, the first pads PAD1, and the second pads PAD2.

In an embodiment of the present disclosure, power lines that provide power to a logic structure are disposed on a back side power network structure. For example, according to an embodiment of the present disclosure, power lines are not provided within the logic structure. Accordingly, in an embodiment of the present disclosure, the degree of integration of the logic structure is increases by further utilizing the area used to implement the power lines. In addition, because more semiconductor devices can be manufactured with the same wafer, the manufacturing yield can be increased.

FIG. 9 is an enlarged view of region “M” of FIG. 8, according to an embodiment. FIG. 10 is an enlarged view of region “M” of FIG. 8, according to another embodiment.

Referring to FIGS. 9 and 10, in an embodiment, the back side power network structure PDN is disposed adjacent to the first die back surface Die1b of the first die Die1.

The back side power network structure PDN includes the power lines PWL, the first signal lines SL1, and the first pads PAD1. The power lines PWL provide power to the logic structure LGS of the first die Die1. The first signal lines SL1 exchange control signals and data signals with the logic structure LGS of the first die Die1.

The power lines PWL and the first signal lines SL1 can be formed together in the same process step. For example, a level (or a location/height) of an upper surface of a power line is to the same as a level (or a location/height) of an upper surface of a first signal line, and a level (or a location/height) of a lower surface of the power line to the same as a level (or a location/height) of a lower surface of the first signal line. For example, the power lines PWL and the first signal lines SL1 include the same conductive material.

The first pads PAD1 are electrically connected to the first signal lines SL1. For example, the first signal lines SL1 and the first pads PAD1 are electrically connected through first vias VI1. The power lines PWL, the first signal lines SL1, and the first pads PAD1 include a conductive metal nitride, such as titanium nitride or tantalum nitride, and/or a metal, such as titanium, tantalum, tungsten, copper, or aluminum.

The second die Die2 is disposed on the first die back surface Die1b of the first die Die1. For example, the second die Die2 is disposed adjacent to the back side power network structure PDN of the first die Die1. The first die back surface Die1b of the first die Die1 and the second front surface Die2a of the second die Die2 are bonded to each other and are coplanar.

The second die Die2 includes the second signal lines SL2 and the second pads PAD2. The second signal lines SL2 exchange control signals and data signals with the L3 cache 133 of the second die Die2.

The second signal lines SL2 and the second pads PAD2 are electrically connected. For example, the second signal lines SL2 and the second pads PAD2 are electrically connected through second vias VI2. The second signal lines SL2, and the second pads PAD2 include a conductive metal nitride, such as titanium nitride or tantalum nitride, and/or a metal, such as titanium, tantalum, tungsten, copper, or aluminum.

Referring to FIG. 9, in an embodiment, the first pads PAD1 of the first die Die1 and the second pads PAD2 of the second die Die2 directly contact each other. The first pads PAD1 and the second pads PAD2 are bonded by using the C2C bonding method. For example, the C2C bonding method includes a hybrid bonding method in which the first pads PAD1 and the second pads PAD2 directly contact each other and are bonded by applying a high temperature and a high pressure thereto.

Referring to FIG. 10, in an embodiment, the first pads PAD1 of the first die Die1 and the second pads PAD2 of the second die Die2 are bonded to each other in the C2C bonding method and are integrally formed together. For example, there is no interface between the first pads PAD1 and the second pads PAD2.

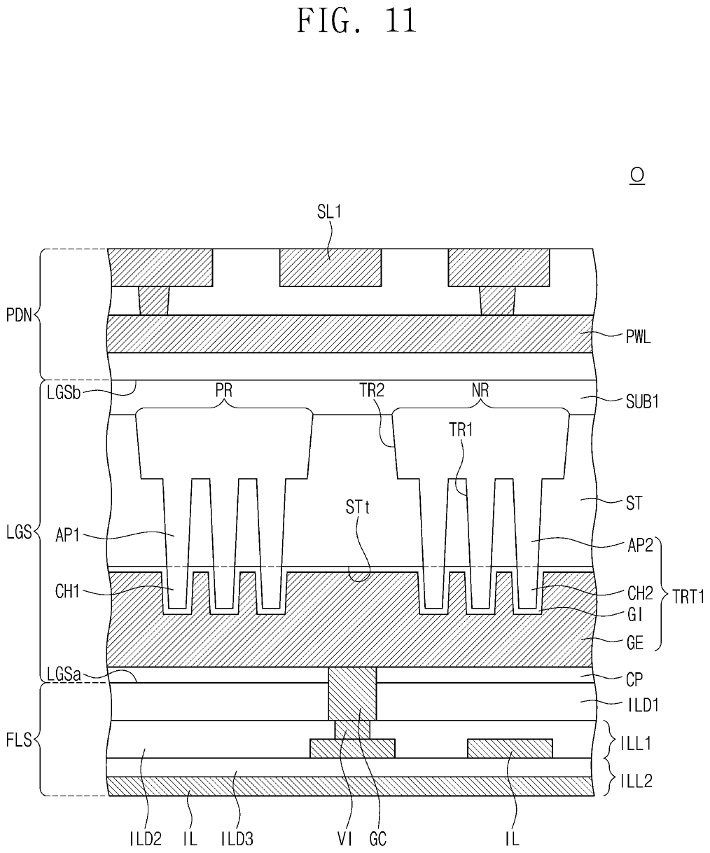

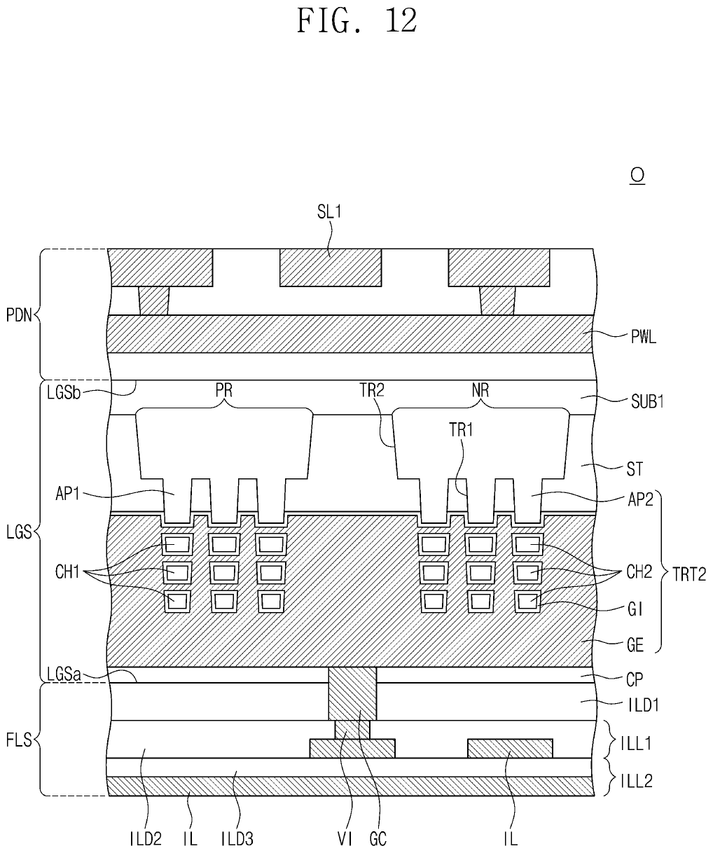

FIG. 11 is an enlarged view of region “O” of FIG. 8, according to an embodiment. FIG. 12 is an enlarged view of region “O” of FIG. 8, according to another embodiment. Below, the logic structure LGS and the back side power network structure PDN will be described in detail with reference to FIGS. 11 and 12.

Referring to FIG. 11, in an embodiment, the first die Die1 includes the logic structure LGS, the front side line structure FLS, and the back side power network structure PDN.

In an embodiment, the logic structure LGS includes first transistors TRT1 disposed on a first substrate SUB1.

The first substrate SUB1 includes a first active region PR and a second active region NR. The first active region PR is a PMOSFET region, and the second active region NR is an NMOSFET region. The first active region PR and the second active region NR are defined by a second trench TR2 formed on an upper portion of the first substrate SUB1.

A plurality of first active patterns AP1 are provided in the first active region PR. A plurality of second active patterns AP2 are provided in the second active region NR. The first and second active patterns AP1 and AP2 vertically protrude from the first substrate SUB1. A first trench TR1 is formed defined between a pair of adjacent active patterns AP1/AP2.

A device isolation layer ST is disposed on the first substrate SUB1. The device isolation layer ST fills the trenches TR. The device isolation layer ST includes a silicon oxide layer.

An upper portion of each of the first active patterns AP1 includes a first channel CH1, and an upper portion of each of the second active patterns AP2 includes a second channel CH2.

The first and second channels CH1 and CH2 are located higher than an upper surface STt of the device isolation layer ST. In an embodiment, the first and second channels CH1 and CH2 vertically protrude from the device isolation layer ST. For example, the first and second channels CH1 and CH2 have a pin shape that protrudes from the device isolation layer ST.

A gate electrode GE is provided that extends across the first and second active patterns AP1 and AP2. The gate electrode GE vertically overlaps the first and second channels CH1 and CH2. The gate electrode GE is formed on an upper surface and opposite sidewalls of each of the first and second channels CH1 and CH2.

A gate dielectric layer GI is disposed between the gate electrode GE and the first and second channels CH1 and CH2. The gate dielectric layer GI extends along a bottom surface of the gate electrode GE. The gate dielectric layer GI covers the upper surface and the opposite sidewalls of each of the first and second channel CH1 and CH2. A gate capping layer CP is disposed on the gate electrode GE. The front surface of the gate capping layer CP is the front surface LGSa of the logic structure LGS.

In an embodiment, the front side line structure FLS is disposed on the front surface LGSa of the logic structure LGS. The front side line structure FLS includes a plurality of interlayer insulating layers ILD1, ILD2, and ILD3 and a plurality of line layers ILL1 and ILL2 disposed on the gate capping layer CP.

The first interlayer insulating layer ILD1, the second interlayer insulating layer ILD2, and the third interlayer insulating layer ILD3 are sequentially stacked on the gate capping layer CP. A gate contact GC is provided that penetrates the first interlayer insulating layer ILD1 and the gate capping layer CP and is electrically connected to the gate electrode GE. The first line layer ILL1 is disposed in the second interlayer insulating layer ILD2. The second line layer ILL2 is disposed in the third interlayer insulating layer ILD3. Each of the first and second line layers ILL1 and ILL2 includes a plurality of lines ILL and a plurality of vias VI. In addition, additional line layers may be further provided on the second line layer ILL2.

In an embodiment, the channels CH1 and CH2 of the first transistors TRT1 are located higher than the upper surface STt of the device isolation layer ST and have a three-dimensional shape. For example, each of the first transistors TRT1 is a three-dimensional transistor. For example, each of the first transistors TRT1 is a FinPET that has a pin-shaped channel.

The back side power network structure PDN is disposed on the back surface LGSb of the logic structure LGS. The back side power network structure PDN includes the plurality of power lines PWL. The plurality of power lines PWL supply power to the integrated circuit of the logic structure LGS. In addition, the plurality of power lines PWL are connected to source/drain regions on the first active pattern AP1 by through holes. A source voltage or a drain voltage can be applied to the source regions or the drain regions through the plurality of power lines PWL and the through holes.

The back side power network structure PDN further includes the plurality of first signal lines SL1. The plurality of first signal lines SL1 transmit control signals and data signals to the integrated circuit. In addition, the plurality of first signal lines SL1 are connected to a gate electrode or source and drain regions of a first transistor by through holes. A control signal and a data signal are transmitted to the processing device 110 (refer to FIG. 2) or the cache controller 120 (refer to FIG. 2) of the logic structure LGS through the plurality of first signal lines SL1 and the through holes.

Referring to FIG. 12, in another embodiment, the logic structure LGS includes second transistors TRT2 disposed on the first substrate SUB1.

A plurality of first channels CH1 are provided on the first active patterns APL. The plurality of first channels CH1 are vertically spaced from each other on the first active patterns AP1. A plurality of channels CH2 are provided on the second active patterns AP2. The plurality of second channels CH2 are vertically spaced from each other on the second active patterns AP2.

The first and second channels CH1 and CH2 are located higher than the upper surface of the device isolation layer ST. For example, a bottom surface of a lowermost first channel CH1 is located higher than the upper surface STt of the device isolation layer ST.

The gate electrode GE surrounds the first and second channels CH1 and CH2. The gate electrode GE is provided on an upper surface, a bottom surface, and opposite sidewalls of each of the plurality of first and second channels CH1 and CH2. The gate dielectric layers GI is interposed between the first and second channels CH1 and CH2 and the gate electrode GE. The gate dielectric layer GI covers the upper surface, the bottom surface, and the opposite sidewalls of each of the first and second channels CH1 and CH2.

In an embodiment, the plurality of channels CH1 and CH2 of the second transistors TRT2 are located higher than the upper surface STt of the device isolation layer ST and have a three-dimensional shape. For example, each of the second transistors TRT2 is a three-dimensional transistor. For example, each of the second transistors TRT2 is a gate-all-around FET (GAAFET) in which a gate surrounds a channel.

The first transistors TRT1, the second transistors TRT2, the lines ILL, and the vias VI of the logic structure LGS can be formed by performing a logic manufacturing process, hereinafter referred to as a “logic process”.

The back side power network structure PDN is disposed on the back surface LGSb of the logic structure LGS. The back side power network structure PDN includes the plurality of power lines PWL. The plurality of power lines PWL supply power to the integrated circuit of the logic structure LGS. In addition, the plurality of power lines PWL are connected to source/drain regions on the second active pattern AP2 by through holes. A source voltage or a drain voltage can be applied to the source regions or the drain regions through the plurality of power lines PWL and the through holes.

The back side power network structure PDN further includes the plurality of first signal lines SL1. The plurality of first signal lines SL1 transmit control signals and data signals to the integrated circuit. In addition, the plurality of first signal lines SL1 are connected to a gate electrode or source and drain regions of a second transistor by through holes. A control signal and a data signal can be transmitted to the processing device 110 or the cache controller 120 of the logic structure LGS through the plurality of first signal lines SL1 and the through holes.

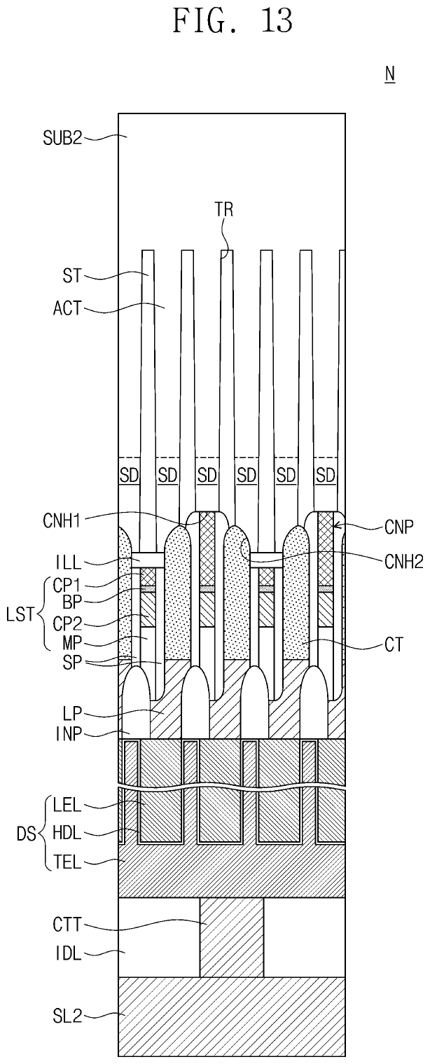

FIG. 13 is an enlarged view of region “N” of FIG. 8.

Referring to FIG. 13, in an embodiment, DRAM cells for storing data are provided on a second substrate SUB2. In detail, a device isolation layer ST that defines active patterns ACT of memory transistors of the DRAM cells is provided on the second substrate SUB2.

The active patterns ACT are formed by patterning the upper portion of the second substrate SUB2. The active patterns ACT extend parallel to the upper surface of the second substrate SUB2. The active patterns ACT are horizontally spaced apart from each other. The width of each of the active patterns ACT decreases as the active pattern ACT extends downward from the upper surface of the second substrate SUB2.

Trenches TR are defined between the active patterns ACT. The device isolation layer ST fills the trenches TR between the active patterns ACT.

Lower portions of the active patterns ACT include source/drain regions SD.

The lower portions of the active patterns ACT further include channel regions CH. In a plan view, each of the channel regions is interposed between a pair of source/drain regions SD.

An insulating layer ILL is disposed on the second substrate SUB2. The insulating layer ILL includes first contact holes CNH1 that expose the source/drain regions SD of the active patterns ACT.

Line structures LST are disposed on the insulating layer ILL. A pair of spacers SP is disposed on opposite sidewalls of each of the line structures LST.

Each line structure LST includes a first conductive pattern CP1, a barrier pattern BP, a second conductive pattern CP2, and a mask pattern MP that are sequentially stacked.

The first conductive pattern CP1 includes a contact portion CNP that fills the first contact hole CNH1 and is in contact with the source/drain region SD. The contact portion CNP is in direct contact with the source/drain region SD.

The barrier pattern BP prevents a metal in the second conductive pattern CP2 from diffusing into the first conductive pattern CP1. The second conductive pattern CP2 is electrically connected to the source/drain region SD through the barrier pattern BP and the first conductive pattern CP1. The second conductive pattern CP2 is a bit line.

Contacts CT are provided that are respectively connected to the source/drain regions SD through the insulating layer ILL. Each contact CT fills a second contact hole CNH2 formed by partially etching the upper portion of the source/drain region SD. The contact CT is in direct contact with the source/drain region SD exposed by the second contact hole CNH2. In addition, the contact CT is in direct contact with the sidewall of a spacer SP and the upper surface of the device isolation layer ST. The contact CT is spaced apart from the adjacent line structure LST by the spacer SP. Each contact CT includes a doped semiconductor material, such as doped silicon or doped germanium.

Landing patterns LP that contact the contacts CT are respectively provided on the contacts CT. The landing patterns LP are respectively electrically connected to the source/drain regions SD through the contacts CT. The landing pattern LP are misaligned with the contact CT. For example, the landing pattern LP are horizontally offset from the center of the contact CT.

An insulating pattern INP is disposed on the mask patterns MP. The insulating pattern INP defines a planar shape of the landing patterns LP. Adjacent landing patterns LP are separated from each other by the insulating pattern INP.

An information storage element DS is disposed on the landing patterns LP. For example, the information storage element DS includes first electrodes LEL disposed on the landing patterns LP. The first electrodes LEL are respectively connected to the landing patterns LP. The information storage element DS further includes a second electrode TEL disposed on and between the first electrodes LEL and a dielectric layer HDL interposed between the first electrodes LEL and the second electrode TEL. The first electrode LEL, the dielectric layer HDL, and the second electrode TEL form a capacitor that stores data.

Each of the first electrodes LEL has a pillar shape whose inside is filled, but is not necessarily limited thereto. According to another embodiment, each of the first electrodes LEL has a cylindrical shape with a closed lower portion. The plurality of first electrodes LEL are arranged in a zigzag pattern to have a honeycomb shape.

An interlayer insulating layer IDL is disposed on the second electrode TEL. The second signal line SL2 is disposed within the interlayer insulating layer IDL. The second signal line SL2 is electrically connected to the second electrode TEL through a plurality of contacts CTT that penetrate the interlayer insulating layer IDL.

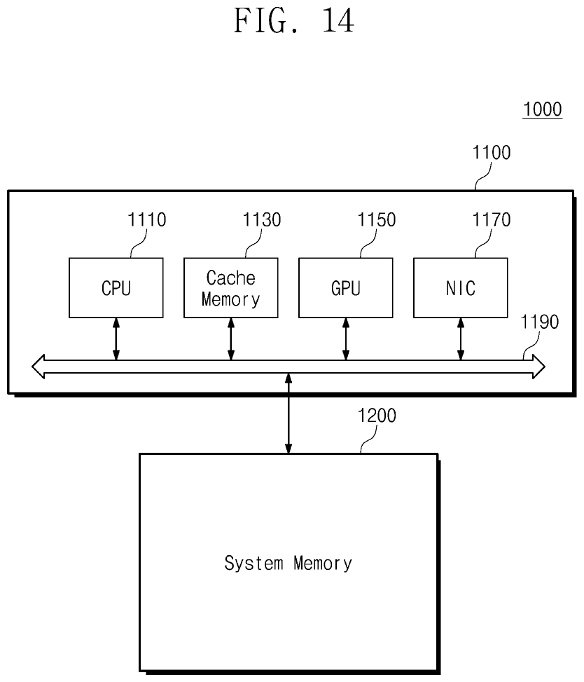

FIG. 14 is a block diagram of a computing system that includes a computing device according to an embodiment of the present disclosure. A computing system 1000 may be one of a desktop computer, a laptop computer, a tablet computer, a smartphone, a wearable device, a server, an electrical vehicle, or a home appliance. Referring to FIG. 14, in an embodiment, the computing system 1000 includes a computing device 1100 and a system memory 1200.

The computing device 1100 can process various arithmetic/logic operations that control overall operations of the computing system 1000. In an embodiment, the computing device 1100 is the computing device 100 of FIG. 1.

The computing device 1100 includes a central processing unit (CPU) 1110, a cache memory 1130, a graphics processing unit (GPU) 1150, a network interface card (NIC) 1170, and a system bus 1190.

The computing device 1100 includes one or more CPU cores, such as a general-purpose central processing unit (CPU), a dedicated application specific integrated circuit (ASIC), and/or an application processor (AP).

The central processing unit 1110 executes various software, such as an application program, an operating system, and a device driver, loaded to the system memory 1200. In an embodiment, the central processing unit 1110 is the processing device 110 of FIG. 1. The central processing unit 1110 executes an operating system (OS) and application programs. The central processing unit 1110 may be a homogeneous multi-core processor or a heterogeneous multi-core processor.

The cache memory 1130 can temporarily store data processed by the central processing unit 1110. The cache memory 1130 includes a memory device that stores data. The cache memory 1130 includes an L1 cache, an L2 cache, and an L3 cache. In an embodiment, the cache memory 1130 is the cache memory 130 of FIG. 1.

The graphics processing unit 1150 performs various graphical computations based on a request of the central processing unit 1110. For example, the graphics processing unit 1150 converts the processed-data into data appropriate for display. A request for streaming access to the system memory 1200 can be issued even by the graphics processing unit 1150. The graphics processing unit 1150 has a computational structure for parallel processing in which similar operations are simultaneously processed. Accordingly, the graphics processing unit 1150 can be used for various high speed parallel computations, in addition to the graphical computations. For example, a process of having a graphics processing unit perform general-purpose operations other than graphic processing operations is known as general-purpose computing on graphics processing units (GPGPU). In addition to video encoding through GPGPU, the graphics processing unit 1150 is used in fields such as molecular structure analysis, decryption, and weather change prediction.

The network interface card 1170 is a communication interface that connects an Ethernet switch or an Ethernet Fabric to the computing system 1000. For example, when the Ethernet switch corresponds to a wired LAN network, the network interface card 1170 is implemented with a wired LAN card. Even when the Ethernet switch corresponds to a wireless LAN, the network interface card 1170 is implemented with hardware that processes a communication protocol that corresponds to the wireless LAN.

The system bus 1190 provides the physical connection between the computing device 1100 and the system memory 1200. For example, the system bus 1190 converts commands, addresses, data, etc. that correspond to various access requests received from the computing device 1100 to be suitable for the interface with system memory 1200. A protocol of the system bus 1190 is at least one of a universal serial bus (USB), a small computer system interface (SCSI), a PCI express, an ATA, a parallel ATA (PATA), a serial ATA (SATA), a serial attached SCSI (SAS), or a universal flash storage (UFS) protocol.

The system memory 1200 stores data for operations of the computing system 1000. For example, the system memory 1200 stores data processed and/or to be processed by the computing device 1100.

The system memory 1200 stores data regardless of whether power is supplied. For example, the system memory 1200 includes a universal flash storage (UFS).

The system memory 1200 includes a volatile/nonvolatile memory device such as a static random access memory (SRAM), a dynamic RAM (DRAM), a synchronous DRAM (SDRAM), a phase-change RAM (PRAM), a ferroelectric RAM (FRAM), a magneto-resistive RAM (MRAM), or a resistive RAM (ReRAM).

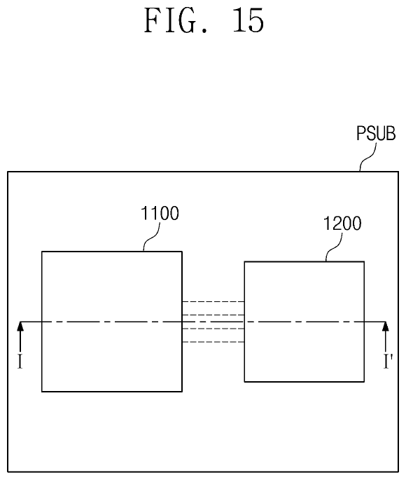

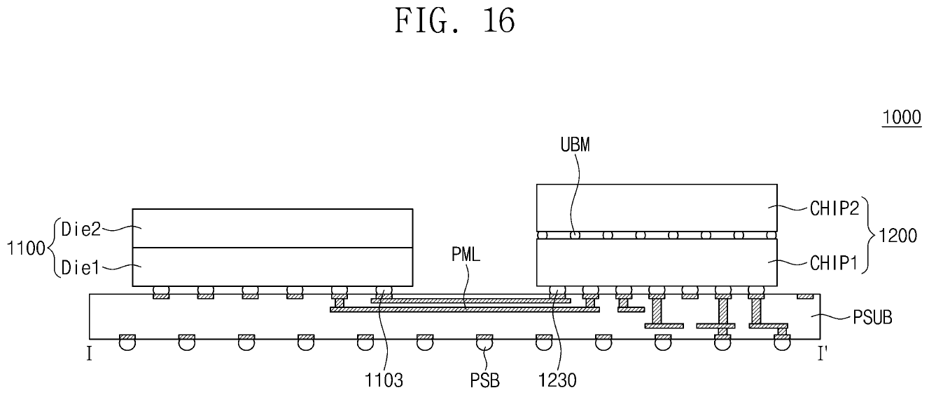

FIG. 15 illustrates a semiconductor device that implements a computing system of FIG. 14. FIG. 16 is a cross-sectional view of a semiconductor device taken along line I-I′ of FIG. 15.

Referring to FIGS. 15 and 16, in an embodiment, a first semiconductor package 1100 and a second semiconductor package 1200 are disposed on a package substrate PSUB. The first semiconductor package 1100 is connected to package lines PML of the package substrate PSUB through first terminals 1103, and the second semiconductor package 1200 is connected to the package lines PML of the package substrate PSUB through second terminals 1230. The first semiconductor package 1100 and the second semiconductor package 1200 can exchange signals with each other through the first terminals 1103, the package lines PML, and the second terminals 1230. The package substrate PSUB is connected to external electronic devices through external terminals PSB.

The first semiconductor package 1100 corresponds to the computing device 1100 of FIG. 14, and the second semiconductor package 1200 corresponds to the system memory 1200 of FIG. 14.

The first semiconductor package 1100 includes the first die Die1 and the second die Die2. The first die Die1 and the second die Die2 are bonded by using the C2C bonding method.

The first die Die1 includes a logic structure, a front side line structure, and a back side power network structure. The front side line structure faces the package substrate PSUB. The back side power network structure is adjacent to the second die Die2.

The first die Die1 includes the central processing unit 1110, the cache memory 1130, the graphics processing unit 1150, the network interface card 1170, and the system bus 1190. In an embodiment, the first die Die1 includes an L1 cache and an L2 cache of the cache memory 1130 of FIG. 14. The second die Die2 includes an L3 cache of the cache memory 1130 of FIG. 14.

The second semiconductor package 1200 includes a first semiconductor chip CHIP1 and a second semiconductor chip CHIP2. Micro bumps UBM are interposed between the first semiconductor chip CHIP1 and the second semiconductor chip CHIP2. For example, the second semiconductor package 1200 is a multi-chip package.

The second semiconductor package 1200 includes the system memory 1200 of FIG. 14. For example, the first semiconductor chip CHIP1 includes a volatile/nonvolatile memory device such as a static random access memory (SRAM), a dynamic RAM (DRAM), a synchronous DRAM (SDRAM), a phase-change RAM (PRAM), a ferroelectric RAM (FRAM), a magneto-resistive RAM (MRAM), or a resistive RAM (ReRAM), and the second semiconductor chip CHIP2 includes a universal flash storage (UFS).

According to an embodiment of the present disclosure, a semiconductor device with reduced power consumption and increased operating speed is provided.

While embodiments of the present disclosure have been described with reference to drawings thereof, it will be apparent to those of ordinary skill in the art that various changes and modifications may be made thereto without departing from the spirit and scope of embodiments of the present disclosure as set forth in the following claims.

What is claimed is:

1. A computing device, comprising:
a first die, including:
a logic structure that includes a processing device that performs computations with respect to data;
a front side line structure disposed on a front surface of the logic structure and that includes lines; and
a back side power network structure disposed on a back surface of the logic structure and that provides power; and
a second die that includes a memory device that stores the data for the computations of the processing device,
wherein the memory device includes a plurality of bank groups that respectively correspond to a plurality of channels, and
wherein the second die is bonded on the back side power network structure by a C2C bonding method.

2. The computing device of claim 1,
wherein the back side power network structure includes:
a power line that provides power to the logic structure;
a first signal line that exchanges a control signal and a data signal with the logic structure; and
a first pad electrically connected to the first signal line,
wherein the second die further includes:
a second signal line that exchanges a control signal and a data signal with the memory device; and
a second pad electrically connected to the second signal line,
wherein the first pad and the second pad are bonded in the C2C bonding method.

3. The computing device of claim 2, wherein a level of an upper surface of the power line is a same as a level of an upper surface of the first signal line, and
wherein a level of a lower surface of the power line is a same as a level of a lower surface of the first signal line.

4. The computing device of claim 2, wherein the first pad and the second pad are integrally formed.

5. The computing device of claim 1, wherein the plurality of channels include a first channel, a second channel, a third channel, and a fourth channel,
wherein each of the first to fourth channels includes a first pseudo channel and a second pseudo channel, and
wherein each of the first pseudo channel and the second pseudo channel is a 64-bit channel.

6. The computing device of claim 5, wherein the plurality of bank groups include first to fourth bank groups that respectively correspond to the first to fourth channels, and
wherein each of the first to fourth bank groups includes a plurality of banks.

7. The computing device of claim 6, wherein each of the banks includes:
a sub-array that includes a plurality of word lines and a plurality of bit lines;
a sub-word line driver that controls the plurality of word lines; and
a sense amplifier connected to the plurality of bit lines.

8. The computing device of claim 7, wherein the number of memory cells connected to each of the plurality of bit lines is 512.

9. The computing device of claim 8, wherein each of the memory cells includes a select element and a capacitive element.

10. The computing device of claim 9, wherein the capacitive element is a capacitor.

11. A computing device, comprising:
a processing device that performs computations with respect to data;
an L1 cache that stores the data for the computations;
an L2 cache that stores the data for the computation, wherein a storage capacity of the L2 cache is greater than a storage capacity of the L1 cache; and
an L3 cache that stores the data for the computation, wherein a storage capacity of the L3 cache is greater than a storage capacity of the L2 cache,
wherein the L3 cache includes a plurality of bank groups that respectively correspond to a plurality of channels, and
wherein the computing device further includes a first die that includes the processing device, the L1 cache, and the L2 cache, and a second die that includes the L3 cache, wherein the first die and the second die are bonded by a C2C bonding method.

12. The computing device of claim 11, wherein the first die includes:
a logic structure that includes the processing unit, the L1 cache, and the L2 cache; and
a back side power network structure that provides power to the logic structure,
wherein the second die is bonded onto the back side power network structure by the C2C bonding method.

13. The computing device of claim 12,
wherein the back side power network structure includes:
a power line that provides e power to the logic structure;
a first signal line that exchange control signals and data signals with the logic structure; and
a first pad electrically connected to the first signal line,
wherein the second die further includes:
a second signal line that exchanges control signals and data signals with the L3 cache; and
a second pad electrically connected to the second signal line,
wherein the first pad and the second pad are bonded by the C2C bonding method.

14. The computing device of claim 13, wherein the first pad and the second pad are integrally formed.

15. The computing device of claim 11, wherein the first die further includes:
a cache controller that retrieves data requested by the processing device from one of the L1 cache, the L2 cache, or the L3 cache.

16. The computing device of claim 15, wherein the cache controller attempts to retrieve the data requested by the processing device from the L1 cache;
when the requested data is absent from the L1 cache, attempts to retrieve the requested data from the L2 cache; and
when the requested data is absent from the L2 cache, attempts to retrieve the requested data from the L3 cache.

17. The computing device of claim 16, wherein each of the L1 cache and the L2 cache is a static random access memory (SRAM), and
the L3 cache is a dynamic random access memory (DRAM).

18. A computing system, comprising:
a central processing unit; and
a system memory,
wherein the central processing unit includes:
a processing device that performs computations with respect to data;
an L1 cache that stores the data for the computations;
an L2 cache that stores the data for the computations, wherein a storage capacity of the L2 cache is greater than a storage capacity of the L1 cache; and
an L3 cache that stores the data for the computations, wherein a storage capacity of the L3 cache is greater than a storage capacity of the L2 cache,
wherein the L3 cache includes a plurality of bank groups that respectively correspond to a plurality of channels, and
wherein the computing system further includes a first die that includes the processing device, the L1 cache, and the L2 cache, and a second die that includes the L3 cache, wherein the first die and the second die are bonded by a C2C bonding method.

19. The computing system of claim 18, wherein the first die further includes a cache controller,
wherein the cache controller attempts to retrieve the data requested by the central processing unit from the L1 cache;
when the requested data is absent from the L1 cache, attempts to retrieve the requested data from the L2 cache;
when the requested data is absent from the L2 cache, attempts to retrieve the requested data from the L3 cache; and
when the requested data is absent from the L3 cache, retrieves the requested data from the system memory.

20. The computing system of claim 19, wherein the first die includes:
A logic structure that includes the processing unit, the L1 cache, and the L2 cache; and
a back side power network structure that provides power to the logic structure,
wherein the second die is bonded onto the back side power network structure by the C2C bonding method.
